(19) United States
(12) Patent Application Publication
(10) Pub. No.: US 2026/0104250 A1
(43) Pub. Date: Apr. 16, 2026

(54) SHAPE PROFILE MEASUREMENT DEVICE, SHAPE PROFILE MEASUREMENT METHOD, AND SEMICONDUCTOR DEVICE MANUFACTURING METHOD INCLUDING THE SAME

(71) Applicant: Samsung Electronics Co., Ltd., Suwon-si (KR)

(72) Inventors: Hyunsoo Kwak, Suwon-si (KR); Jungwon Kim, Daejeon-si (KR); Hyoungsu Choi, Daejeon-si (KR); Sungyoon Ryu, Suwon-si (KR); Younghoon Sohn, Suwon-si (KR); Jinho Bae, Daejeon-si (KR)

(73) Assignees: Samsung Electronics Co., Ltd., Suwon-si (KR); KOREA ADVANCED INSTITUTE OF SCIENCE AND TECHNOLOGY, Daejeon (KR)

(21) Appl. No.: 19/275,380

(22) Filed: Jul. 21, 2025

(30) Foreign Application Priority Data
Oct. 10, 2024 (KR) 10-2024-0138027
Dec. 2, 2024 (KR) 10-2024-0176900

(51) Int. Cl. G01B 11/25; H01L 21/66

(52) U.S. Cl. CPC G01B 11/2518; H10P 74/203

(57) ABSTRACT

A shape profile measurement device includes a light source emitting an optical pulse stream, a relay optical system configured to receive the optical pulse stream, generate an electrical pulse stream from a first portion of the optical pulse stream, generate a chromatically dispersed light over a plurality of wavelengths from a second portion of the optical pulse stream, provide the chromatically dispersed light to a measurement target, and output a reflected optical pulse stream reflected from the measurement target, a detector configured to receive the electrical pulse stream and the reflected optical pulse stream and detect a phase difference between the electrical pulse stream and the reflected optical pulse stream, and a processor configured to generate a shape profile of the measurement target using the phase difference.

### CROSS-REFERENCE TO RELATED APPLICATION

This application is based on and claims priority under 35 U.S.C. § 119 to Korean Patent Application Nos. 10-2024-0138027, filed on Oct. 10, 2024, and 10-2024-0176900, filed on Dec. 2, 2024, in the Korean Intellectual Property Office, the disclosures of each of which are incorporated by reference herein in their entireties.

### BACKGROUND

The inventive concept relates to a shape profile measurement device, a shape profile measurement method, and a semiconductor device manufacturing method including the same, and more particularly, to a shape profile measurement device using a time of flight (TOF), a shape profile measurement method using the TOF, and a semiconductor device manufacturing method including the same.

As semiconductor device integration increases, vertical semiconductor device structures have been proposed to replace conventional planar structures. Vertical-structured semiconductor devices include a structure extending in the vertical direction on a substrate. However, as the integration of semiconductor devices increases, the number of vertically stacked layers also increases, creating a demand for precise measurement methods for semiconductor devices.

### SUMMARY

The inventive concept provides a shape profile measurement device with improved reliability, a shape profile measurement method with improved reliability, and a semiconductor device manufacturing method including the same.

The inventive concept also provides a shape profile measurement device with improved measurement speed, a shape profile measurement method with improved measurement speed, and a semiconductor device manufacturing method including the same.

In addition, the problems to be solved by the technical idea of the inventive concept are not limited to the problems mentioned above, and other problems could be clearly understood by those of ordinary skill in the art from the description below.

According to an aspect of the present disclosure, a shape profile measurement device includes a light source configured to generate and emit an optical pulse stream, a relay optical system configured to receive the optical pulse stream which is deflected into a first portion of the optical pulse stream and a second portion of the optical pulse stream, generate an electrical pulse stream from the first portion of the optical pulse stream, generate a chromatically dispersed light over a plurality of wavelengths from the second portion of the optical pulse stream, provide the chromatically dispersed light to a measurement target, and output a reflected optical pulse stream reflected from the measurement target, a detector configured to receive the electrical pulse stream and the reflected optical pulse stream from the relay optical system and detect a phase difference between the electrical pulse stream and the reflected optical pulse stream, and a processor configured to generate a shape profile of the measurement target using the phase difference.

According to an aspect of the present disclosure, a shape profile measurement device includes a light source configured to emit an optical pulse stream, a relay optical system comprising a deflector configured to receive the optical pulse stream and deflect the optical pulse stream into a first portion of the optical pulse stream and a second portion of the optical pulse stream, an electrical pulse stream generator configured to convert the first portion of the optical pulse stream into an electrical pulse stream, a scanning system configured to change a traveling direction of the second portion of the optical pulse stream, and a chromatic aberration generator configured to receive the second portion of the optical pulse stream from the scanning system, disperse the second portion of the optical pulse stream over a plurality of wavelengths to generate a chromatically dispersed light, and output the chromatically dispersed light to a measurement target, a detector configured to receive a reflected optical pulse stream reflected from the measurement target as a line scan image and the electrical pulse stream, and a processor configured to generate a shape profile of the measurement target based on the line scan image.

According to an aspect of the present disclosure, a shape profile measurement method includes generating and emitting an optical pulse stream, deflecting the optical pulse stream into a first portion of the optical pulse stream and a second portion of the optical pulse stream, generating an electrical pulse stream by converting the first portion of the optical pulse stream to the electrical pulse stream, probing a measurement target with the second portion of the optical pulse stream, and measuring a surface profile of the measurement target based on a reflected optical pulse stream reflected from the measurement target and the electrical pulse stream. The probing of the measurement target includes changing a traveling direction of the optical pulse stream to scan the measurement target, and dispersing the optical pulse stream over a plurality of wavelengths to generate a chromatically dispersed light.

### BRIEF DESCRIPTION OF THE DRAWINGS

Embodiments of the inventive concept will be more clearly understood from the following detailed description taken in conjunction with the accompanying drawings in which:

FIG. 1 illustrates a shape profile measurement device according to some embodiments;

FIG. 2 illustrates a method of measuring a pattern based on a high-speed scanning system and a second optical element, according to some embodiments;

FIG. 3 shows graphs illustrating a method of measuring a phase difference between an electrical pulse stream and an optical pulse stream, according to some embodiments;

FIG. 4 is a cross-sectional view of a measurement target including a pattern, according to some embodiments;

FIG. 5 illustrates a shape profile measurement device according to some embodiments;

FIG. 6 illustrates a shape profile measurement device according to some embodiments;

FIG. 7 illustrates a shape profile measurement device according to some embodiments;

FIG. 8 is a flowchart illustrating a shape profile measurement method according to some embodiments;

FIG. 9 is a schematic block diagram of a shape profile measurement device according to some embodiments; and

FIG. 10 is a flowchart illustrating a semiconductor device manufacturing method including a shape profile measurement method, according to some embodiments.

### DETAILED DESCRIPTION OF THE EMBODIMENTS

Hereinafter, embodiments are described in detail with reference to the accompanying drawings. Like reference numerals in the drawings denote like elements, and thus their repetitive description will be omitted. In the drawings, the thicknesses or sizes of layers are exaggerated for convenience and clarity of description, and accordingly, may be somewhat different from actual shapes and ratios.

The terms, e.g., “beneath”, “below”, “under”, “on”, and “above”, indicating positions in a space are to describe the relative position relationships between elements or patterns shown in the drawings, are only for easiness of understanding, and do not have any intention to limit the technical idea of the inventive concept. The terms for the relative positions in a space intend to include changes according to a direction of a semiconductor device in addition to a direction described in the drawings. That is, the semiconductor device may be oriented in various directions in use (or in manufacturing), and even in this case, the terms for positions used in the specification will be easily understood by those of ordinary skill in the art.

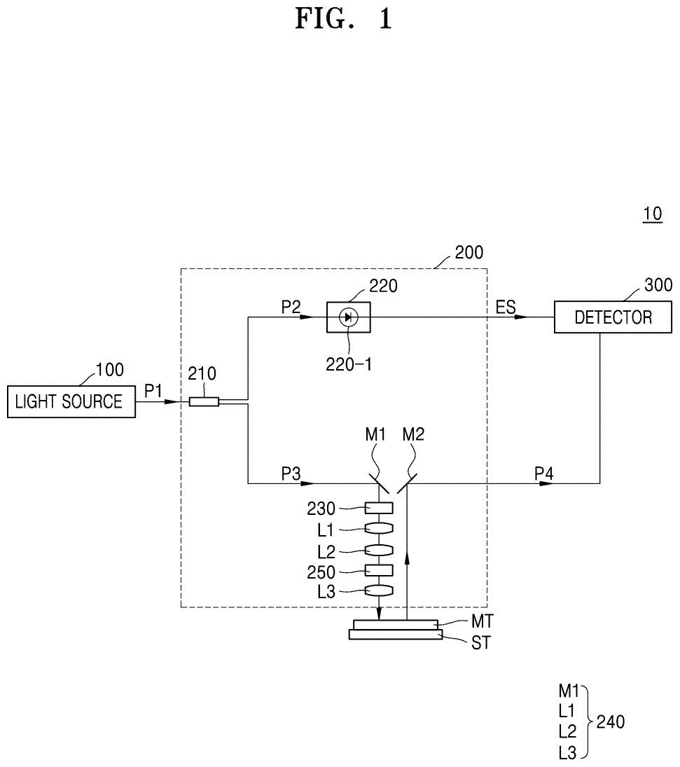

FIG. 1 illustrates a shape profile measurement device 10 according to some embodiments.

Referring to FIG. 1, the shape profile measurement device 10 may include a light source 100, a relay optical system 200, and a detector 300. The shape profile measurement device 10 may measure a measurement target MT based on an optical pulse stream reflected from the measurement target MT including a pattern. The shape profile measurement device 10 may perform line scan on the measurement target MT including the pattern. The shape profile measurement device 10 may measure the measurement target MT by applying an optical pulse onto the upper surface of the measurement target MT.

The light source 100 may be configured to periodically output an optical pulse. The light source 100 may be configured to emit a first optical pulse stream P1. The light source 100 may include a first laser light source, and the first laser light source may be a femtosecond laser configured to generate a femtosecond-scale optical pulse. In some embodiments, the light source 100 may include a mode-locked laser, an optical frequency comb, a titanium (Ti)-sapphire laser, and/or a second harmonic generation (SHG) laser.

The light source 100 may be configured to output an optical pulse of a wavelength band having a high reflectivity with respect to the measurement target MT. In an embodiment, the wavelength band may include a plurality of wavelengths separated from each other. The optical pulse may be dispersed over the plurality of wavelengths by a second optical element 250, which will be described below. In some embodiments, the light source 100 may be configured to output an optical pulse of a wavelength band having a high reflectivity with respect to silicon. For example, the light source 100 may be configured to output an optical pulse of a wavelength band having a reflectivity of 90 % or higher with respect to silicon. For example, the light source 100 may be configured to output an optical pulse having a wavelength of 1,000 nm or lower.

The relay optical system 200 may allow the optical pulse stream generated by the light source 100 to be incident to the measurement target MT. In addition, the relay optical system 200 may relay an optical pulse stream reflected from the measurement target MT to the detector 300. The relay optical system 200 may include an optical coupler 210 (i.e., a deflector), an electrical pulse stream generator 220, a scanning system 230, a first optical element 240, and a second optical element 250 (i.e., a chromatic aberration generator).

The optical coupler 210 may split the first optical pulse stream P1. The optical coupler 210 may split the first optical pulse stream P1 into a second optical pulse stream P2 and a third optical pulse stream P3. For example, the optical coupler 210 may deflect the first optical pulse stream P1 into the second optical pulse stream P2 and the third optical pulse stream P3. The second optical pulse stream P2 may be input to the electrical pulse stream generator 220, and the third optical pulse stream P3 may be input to the measurement target MT to be measured.

The electrical pulse stream generator 220 may receive the second optical pulse stream P2. The electrical pulse stream generator 220 may perform photoelectric conversion on the second optical pulse stream P2 input thereto and output an electrical pulse stream ES. In some embodiments, the electrical pulse stream generator 220 may include a photoelectric device 220-1 configured to convert an optical signal into an electrical signal. For example, the photoelectric device 220-1 of the electrical pulse stream generator 220 may include a positive-intrinsic-negative (PIN) optical diode and/or a uni-travelling-carrier (UTC) optical diode.

The third optical pulse stream P3 may be incident to the measurement target MT through the scanning system 230, the first optical element 240, and the second optical element 250. The scanning system 230 may be configured to control the behavior of the third optical pulse stream P3. For example, the scanning system 230 may include a galvano scanner and/or a rotating mirror to move the third optical pulse stream P3, thereby scanning or probing the measurement target MT. In an embodiment, the Galvano scanner may control the angle of a light beam. In an embodiment, the rotating mirror may change the traveling direction of an incident light depending on the mirror's angular position. The first optical element 240 may control the third optical pulse stream P3 to be incident to the measurement target MT. For example, the first optical element 240 may include a beam splitter and/or a lens. In some embodiments, the first optical element 240 may include a first mirror M1, a first lens L1, a second lens L2, and a third lens L3. However, the configuration of the first optical element 240 is not limited thereto, and the first optical element 240 may include other components by which the third optical pulse stream P3 may be controlled to be incident to the measurement target MT.

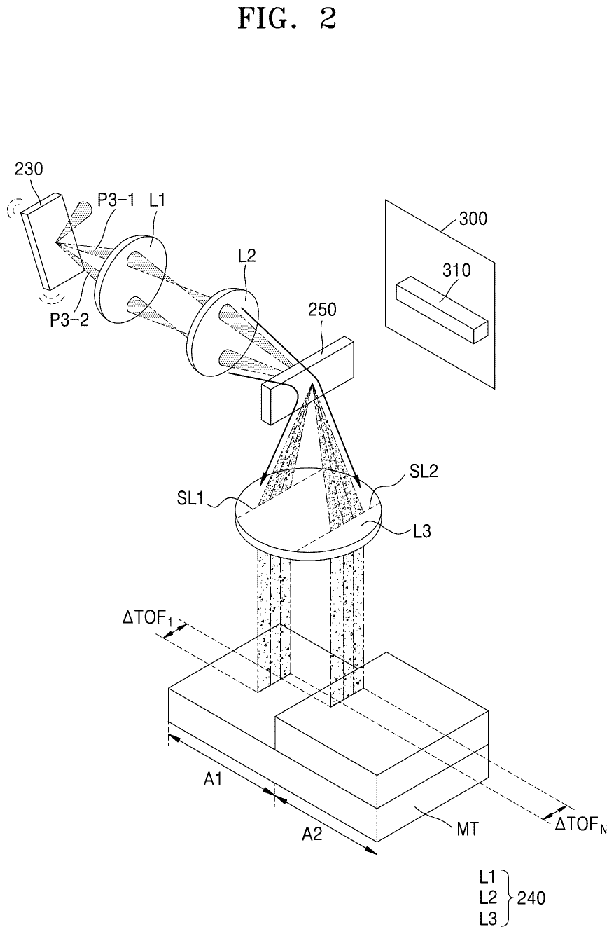

The second optical element 250 may split or disperse the third optical pulse stream P3 according to wavelengths. For example, the third optical pulse stream P2 may be a wavelength band including a plurality of wavelengths, and the second optical element 250 may spatially disperse the plurality of wavelengths to generate a chromatically dispersed light which has the plurality of wavelengths spatially dispersed. Therefore, the shape profile measurement device 10 may measure the measurement target MT at a plurality of wavelengths. For example, the second optical element 250 may include a prism, a diffracting grating, or a spectrometer. However, the technical idea of the inventive concept is not limited thereto, and other devices capable of splitting an optical pulse stream according to wavelengths may be used. The scanning system 230 and the second optical element 250 are described in more detail with reference to FIG. 2.

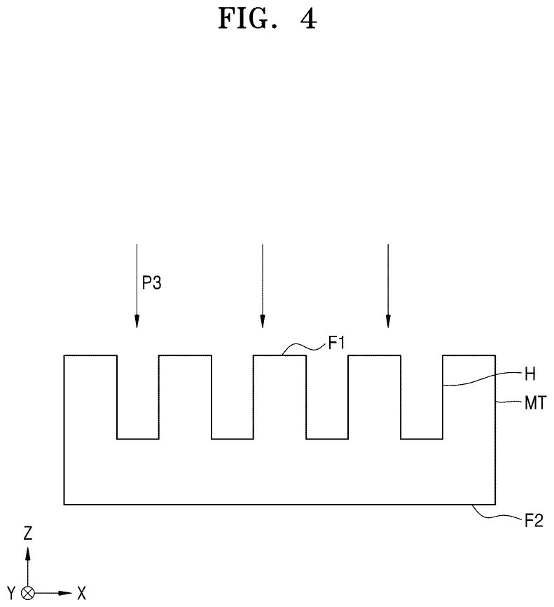

The measurement target MT to be measured by the shape profile measurement device 10 may include a pattern. In some embodiments, the measurement target MT may include a high aspect ratio contact (HARC) pattern. The measurement target MT including a pattern is described in more detail with reference to FIGS. 2 and 4.

The shape profile measurement device 10 may further include a stage ST. The stage ST may support the measurement target MT to be measured. The stage ST may move the measurement target MT in a horizontal direction (the X direction and/or the Y direction) and/or the vertical direction (the Z direction) or rotate the measurement target MT around the vertical direction (the Z direction) as an axis such that the measurement target MT is aligned with respect to the relay optical system 200 configured to relay the third optical pulse stream P3.

A fourth optical pulse stream P4 (i.e., a reflected optical pulse stream) reflected from the measurement target MT may be input to the detector 300 through a second mirror M2. In some embodiments, the second mirror M2 may be omitted. The detector 300 may detect the electrical pulse stream ES and the fourth optical pulse stream P4 reflected from the measurement target MT. The detector 300 may be configured to detect the phase difference between the electrical pulse stream ES and the fourth optical pulse stream P4. In some embodiments, the detector 300 may be configured to output an electrical signal proportional to the phase difference between the electrical pulse stream ES and the fourth optical pulse stream P4 by using photoelectric sampling. Herein, the electrical pulse stream ES is generated by converting the second optical pulse stream P2 input to the electrical pulse stream generator 220.

The detector 300 may include a phase detector. In some embodiments, the detector 300 may include an optical phase detector. For example, the detector 300 may include a fiber loop-based optical-microwave phase detector (FLOM-PD) using a Sagnac loop interferometer, a 3×3 coupler-based phase detector, and/or a balanced optical-microwave phase detector (BOM-PD).

In some embodiments, the detector 300 may further include a balanced photodetector (BPD).

In another embodiment, the detector 300 may image the measurement target MT based on the fourth optical pulse stream P4 and the electrical pulse stream ES. The detector 300 may image a measurement area of the measurement target MT. In an embodiment, the detector 300 may further include a line scan camera 310 as shown in FIG. 2. The detector 300 may acquire the intensity of light in each area of the measurement target MT (e.g., each pixel of a captured image of the measurement target MT). For example, the line scan camera 310, as shown in FIG. 2, may generate a line scan image from the fourth optical pulse stream P4 corresponding to the chromatically dispersed light reflected from the measurement target MT. The line scan image may include a plurality of regions corresponding to the plurality of wavelengths, respectively. The detector 300 may detect a plurality of intensities of the plurality of regions of the line scan image. The shape of the measurement target MT may be measured based on the intensity of light in each area of the measurement target MT (i.e., a corresponding region of the line scan image) and the wavelength band of an incident optical pulse stream. The intensity of light may be proportional to a time of flight (TOF). Therefore, the shape of the measurement target MT may be measured based on the intensity of light and the wavelength band of an optical pulse stream.

The shape profile measurement device 10 may measure the measurement target MT by using a TOF scheme. In more detail, the shape profile measurement device 10 may measure the depth of the pattern of the measurement target MT based on the phase difference between the electrical pulse stream ES, which is a reference signal, and the fourth optical pulse stream P4 reflected from the measurement target MT.

FIG. 2 illustrates a method of measuring a pattern based on a high-speed scanning system and a second optical element, according to some embodiments. A description is made with reference to FIG. 1 together.

Referring to FIG. 2, the scanning system 230, the first optical element 240, the second optical element 250, and the measurement target MT are illustrated. In addition, although FIG. 2 illustrates that the first optical element 240 includes the first to third lenses L1, L2, and L3, the technical idea of the inventive concept is not limited thereto.

The measurement target MT may include a plurality of areas. For example, the measurement target MT may include a first area A1 and a second area A2. The first area A1 of the measurement target MT may have a lower vertical level than the second area A2 of the measurement target MT. When an optical pulse stream incident to the measurement target MT is incident to different areas, a path difference of the optical pulse stream may occur. The shape profile measurement device 10 may measure a pattern based on the path difference.

As described above, the scanning system 230 may easily control an optical pulse stream. For example, the scanning system 230 may quickly and precisely move an optical pulse stream, thereby scanning or probing the measurement target MT. For example, the scanning system 230 may sequentially generate, from the third optical pulse stream P3, a first optical pulse stream P3-1 and a second optical pulse stream P3-2. For the simplicity, the scanning system 230 is described to generate two optical pulse streams from the third optical pulse stream P3. The scanning system 230 may sequentially generate more than two optical pulse streams to scan or probe the measurement target MT. Therefore, even when the stage ST does not move, the scanning system 230 may easily control an incident position of an optical pulse stream on the measurement target MT.

In addition, as described above, the second optical element 250 may split an optical pulse stream for each wavelength band. For example, the second optical element 250 may disperse the first optical pulse stream P3-1 along a first scan line SL1, and the second optical pulse stream P3-2 along a second scan line SL2. The detector 300 may detect the first optical pulse stream P3-1 reflected from the first scan line SL1 as a first line scan image and the second optical pulse stream P3-2 reflected from the second scan line SL2 as a second line scan image. Therefore, the shape profile measurement device 10 may measure a TOF ΔTOF₁ in a first wavelength band to a TOF ΔTOF_{N} in an N-th wavelength band (N is a natural number greater than or equal to 2). Therefore, the shape profile measurement device 10 may measure adjacent areas of the measurement target MT at the same time by using different wavelength bands. Therefore, the shape profile measurement device 10 may quickly measure the measurement target MT. For the convenience of description, the chromatically dispersed light is referred to as having a plurality of wavelengths, instead of a plurality of wavelength bands. For example, separated light by a prism may include a plurality of wavelength bands, rather than a plurality of wavelengths distinctly separated from each other. For example, a red color has a band from about 620 nm to 750 nm, not a single wavelength. In this application, a wavelength and a wavelength band can be interchangeably used.

In addition, a line scan image may be acquired based on the position of each area of the measurement target MT, a TOF in each area of the measurement target MT, and an electrical pulse stream. The line scan image may be acquired based on the electrical pulse stream and an encoded optical pulse. The encoded optical pulse may include information on the position of each area of the measurement target MT and the TOF in each area of the measurement target MT. The electrical pulse stream and the encoded optical pulse may be input to a phase detector to acquire an electro-optic sampling timing detection (EOS-TD) output spectrum. Thereafter, the EOS-TD output spectrum may be incident to the line scan camera 310, thereby acquiring the line scan image.

The shape profile measurement device 10 of the inventive concept may include the scanning system 230 and the second optical element 250 configured to disperse an optical pulse stream, thereby quickly and precisely measuring the measurement target MT. In more detail, the scanning system 230 may control an optical pulse stream at a high speed, and the second optical element 250 may disperse the optical pulse stream such that the measurement target MT is measured at various wavelengths.

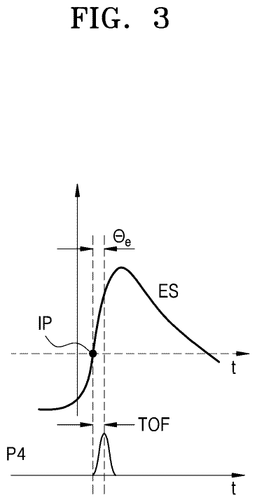

FIG. 3 shows graphs illustrating a method of measuring the phase difference between an electrical pulse stream and an optical pulse stream, according to some embodiments. A description is made with reference to FIG. 1 together.

The upper graph of FIG. 3 shows the intensity of the electrical pulse stream ES over time, and the lower graph of FIG. 3 shows the intensity of the fourth optical pulse stream P4 over time. The horizontal axis of the upper graph of FIG. 3 indicates time, and the vertical axis thereof indicates the intensity of the electrical pulse stream ES. The horizontal axis of the lower graph of FIG. 3 indicates time, and the vertical axis thereof is not shown but indicates the intensity of the fourth optical pulse stream P4. The upper and lower graphs of FIG. 3 are aligned with each other such that the same position on the horizontal axis indicates the same time. For example, the graphs are obtained in the same time domain.

Referring to FIG. 3, there may occur the phase difference between the electrical pulse stream ES and the fourth optical pulse stream P4. The phase difference between the electrical pulse stream ES and the fourth optical pulse stream P4 may be θₑ. The shape profile measurement device 10 may measure a delay time of the fourth optical pulse stream P4 based on the phase difference and measure a pattern based on the delay time. The detector 300 of FIG. 1 may output an electrical signal proportional to the phase difference between the electrical pulse stream ES and the fourth optical pulse stream P4 by using photoelectric sampling.

The detector 300 may detect the phase difference between the electrical pulse stream ES and the fourth optical pulse stream P4 by using a rising edge or a falling edge, which is a particular position, of the electrical pulse stream ES. For example, the detector 300 may detect a phase difference at a particular point of the rising edge. Herein, an arbitrary point of the rising edge may be used as the particular point. In particular, because a linearly usable phase (timing) area is widest in both directions at an intermediate point IP of the rising edge, the intermediate point of the rising edge may be used as the particular point that is a reference for phase difference detection. In an embodiment, the intermediate point IP of the rising edge may be aligned with a peak of the third optical pulse stream P3, and thus a time difference (i.e., a time delay) between the peak of the fourth optical pulse stream P4 and the intermediate point IP of the rising edge may correspond to a phase difference between the electrical pulse stream ES and the fourth optical pulse stream P4. In an embodiment, during the conversion of the second optical pulse stream P2 into the electrical pulse stream ES, the phase information of the second optical pulse stream P2 may be preserved. Accordingly, the electrical pulse stream ES maintains the same phase as the second optical pulse stream P2, enabling a phase comparison between the electrical pulse stream ES and the fourth optical pulse stream P4.

Although FIG. 3 illustrates that the phase difference between the electrical pulse stream ES and the fourth optical pulse stream P4 is measured at the rising edge of the electrical pulse stream ES, as described above, the phase difference between the electrical pulse stream ES and the fourth optical pulse stream P4 may be measured at the falling edge of the electrical pulse stream ES.

FIG. 4 is a cross-sectional view of the measurement target MT including a pattern, according to some embodiments. A description is made with reference to FIG. 1 together.

Referring to FIG. 4, the measurement target MT may include a first face F1 and a second face F2 that is opposite to the first face F1. The first face F1 may be spaced apart from the second face F2 in the vertical direction (the Z direction). The measurement target MT may include a pattern. In some embodiments, the measurement target MT may include one or more holes H formed by removing at least a portion of the measurement target MT in the vertical direction (the Z direction).

The first face F1 may be the front surface of the measurement target MT, and the second face F2 may be the back surface of the measurement target MT. The front surface of the measurement target MT may be a surface on which the pattern is formed, and the back surface of the measurement target MT may be a surface opposite to the front surface.

As described above, the third optical pulse stream P3 for measuring the measurement target MT may be first incident to the first face F1 of the measurement target MT. That is, the third optical pulse stream P3 may be first incident to the front surface of the measurement target MT. Because the third optical pulse stream P3 is incident to the front surface of the measurement target MT, as the intensity of an optical pulse stream reflected from the measurement target MT increases, the shape profile measurement device 10 may measure the measurement target MT with high reliability. Therefore, the shape profile measurement device 10 may measure the measurement target MT based on an optical pulse stream of a wavelength band having a high reflectivity with respect to the measurement target MT. Since the third optical pulse stream P3 with a high reflectivity is incident on the front surface of the measurement target MT, reflection from the back surface of the measurement target MT may avoided, thereby enabling the shape profile measurement device 10 to measure the surface profile of the front surface of the measurement target MT with high reliability. The high reflectivity refers to a level of reflectivity sufficient to substantially avoid reflection from the back surface of the measurement target MT from affecting reflection from the front surface. In one embodiment, the high reflectivity may be 90% or greater with respect to silicon.

In some embodiments, the measurement target MT may be manufactured from a wafer W. The measurement target MT may be manufactured by forming a pattern (e.g., the one or more holes H) on the wafer W. For example, the measurement target MT may include silicon.

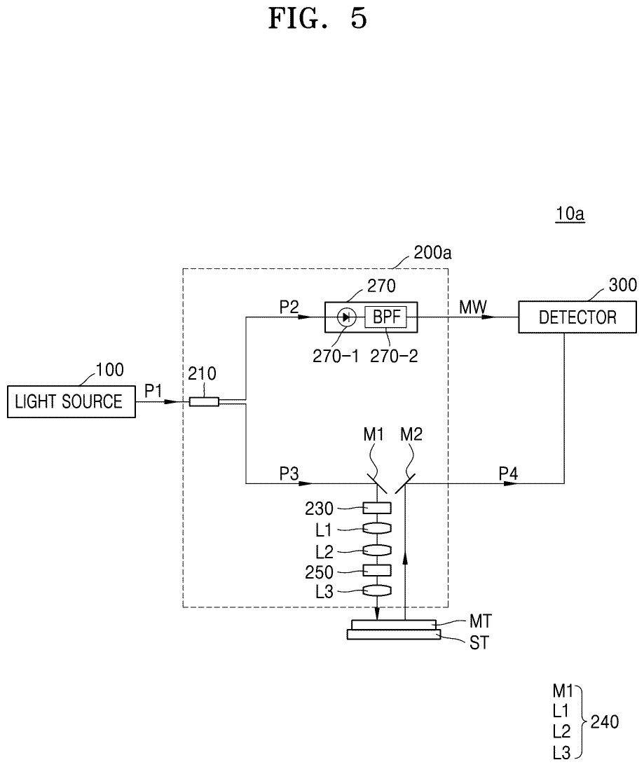

FIG. 5 illustrates a shape profile measurement device 10a according to some embodiments. A description is made with reference to FIG. 1 together.

The shape profile measurement device 10a of FIG. 5 is substantially the same as the shape profile measurement device 10 of FIG. 1 except that the former includes a sine wave generator 270, and thus, the sine wave generator 270 is mainly described.

Referring to FIG. 5, the shape profile measurement device 10a may include the light source 100, a relay optical system 200a, and the detector 300. The relay optical system 200a may include the optical coupler 210, the scanning system 230, the first optical element 240, the second optical element 250, the second mirror M2, and the sine wave generator 270.

The sine wave generator 270 may include a photoelectric device 270-1 configured to output an electrical pulse stream by performing photoelectric conversion on an input optical pulse stream and a bandpass filter (BPF) 270-2. That is, the sine wave generator 270 may further include the BPF 270-2 in addition to the electrical pulse stream generator 220 of FIG. 1. Once the electrical pulse stream output from the photoelectric device 270-1 passes through the BPF 270-2, one frequency among a plurality of frequencies of the electrical pulse stream may be output as a sinusoidal microwave MW. The detector 300 may output an electrical signal based on the phase difference between the microwave MW output from the electrical pulse stream and the fourth optical pulse stream P4. The detector 300 may detect a phase difference with respect to zero crossing of the microwave MW output from the sine wave generator 270. The zero crossing of the microwave MW refers to the point in time when a microwave waveform crosses the zero voltage level.

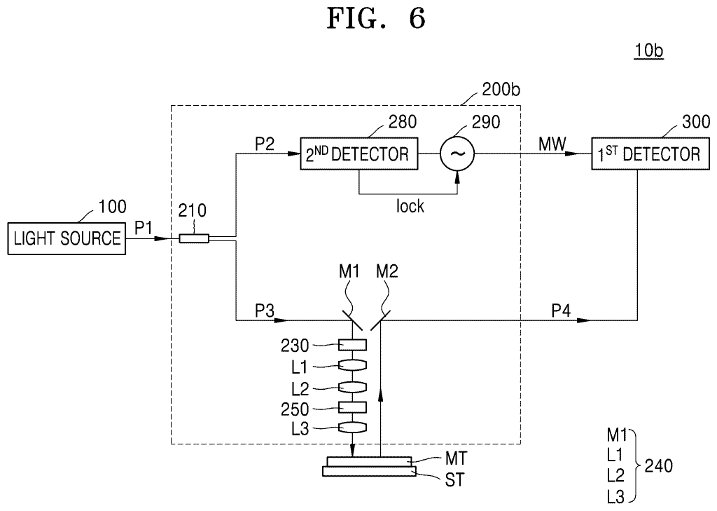

FIG. 6 illustrates a shape profile measurement device 10b according to some embodiments. A description is made with reference to FIG. 1 together.

The shape profile measurement device 10b of FIG. 6 is substantially the same as the shape profile measurement device 10 of FIG. 1 except that the former includes a second detector 280 and a radio frequency (RF) signal source 290, and thus, the second detector 280 and the RF signal source 290 are mainly described.

Referring to FIG. 6, the shape profile measurement device 10b may include the light source 100, a relay optical system 200b, and a first detector 300. The relay optical system 200b may include the optical coupler 210, the scanning system 230, the first optical element 240, the second optical element 250, the second mirror M2, the second detector 280, and the RF signal source 290. In addition, the first detector 300 may be substantially the same as the detector 300 described with reference to FIG. 1.

The second detector 280 may detect the second optical pulse stream P2 generated by the light source 100. The second detector 280 may detect the microwave MW generated by the RF signal source 290. The second detector 280 may measure the phase (timing) difference between the second optical pulse stream P2 and the microwave MW. The second detector 280 may feed, back to the RF signal source 290, a signal for compensating for the phase (timing) difference between the second optical pulse stream P2 and the microwave MW. Therefore, the RF signal source 290 may output a reference signal synchronized with the light source 100. That is, the microwave MW may be phase-locked with the second optical pulse stream P2 of the light source 100. The RF signal source 290 is an independent signal source and may include, for example, a voltage controlled oscillator (VCO).

The first detector 300 may detect the microwave MW generated by the RF signal source 290 and the fourth optical pulse stream P4. The first detector 300 may measure the phase (timing) difference between the microwave MW and the fourth optical pulse stream P4. The first detector 300 may output an electrical signal proportional to the phase difference based on photoelectric sampling.

In another embodiment, the first detector 300 may detect a portion of the fourth optical pulse stream P4 to image the measurement target MT. The first detector 300 may image a measurement area of the measurement target MT.

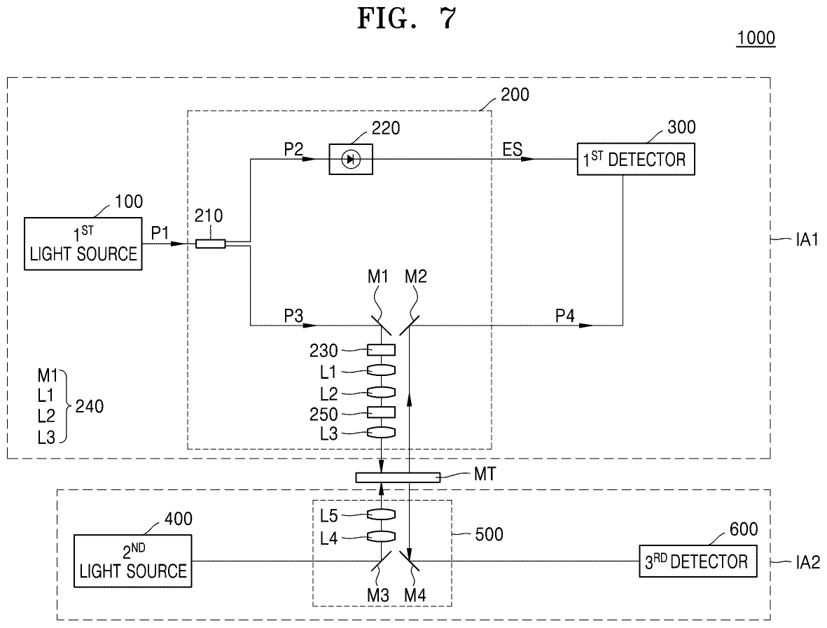

FIG. 7 illustrates a shape profile measurement device 1000 according to some embodiments. A description is made with reference to FIGS. 1, 5, and 6 together.

Referring to FIG. 7, the shape profile measurement device 1000 may include a first shape profile measurement device IA1 and a second shape profile measurement device IA2. The first shape profile measurement device IA1 may be configured to measure the measurement target MT by applying light onto the front surface of the measurement target MT, and the second shape profile measurement device IA2 may be configured to measure the measurement target MT by applying light onto the back surface of the measurement target MT. The first shape profile measurement device IA1 may include at least one of the shape profile measurement devices 10, 10a, and 10b of FIGS. 1, 5, and 6.

The first shape profile measurement device IA1 and the second shape profile measurement device IA2 may measure the measurement target MT by using different wavelength bands of light. In some embodiments, the first shape profile measurement device IA1 may measure the measurement target MT based on an optical signal of a wavelength band having a high reflectivity with respect to the measurement target MT, and the second shape profile measurement device IA2 may measure the measurement target MT based on an optical signal of a wavelength band having a high transmittance with respect to the measurement target MT.

The first shape profile measurement device IA1 may include a first light source 100, a first relay optical system 200, and a first detector 300, and the second shape profile measurement device IA2 may include a second light source 400, a second relay optical system 500, and a third detector 600. The first light source 100, the first relay optical system 200, and the first detector 300 of the first shape profile measurement device IA1 are substantially the same as the light source 100, the relay optical system 200, and the detector 300 of FIG. 1, and thus, a detailed description thereof is omitted herein. As described above, the first shape profile measurement device IA1 may measure the measurement target MT by inputting an optical pulse stream onto the upper surface of the measurement target MT.

The second light source 400 may generate and emit an optical signal for measuring the measurement target MT. The second relay optical system 500 may be configured to allow the optical signal generated by the second light source 400 to be incident to the measurement target MT. In addition, the second relay optical system 500 may be configured to relay an optical signal reflected from the measurement target MT to the third detector 600. For example, the second relay optical system 500 may include a fourth lens L4, a fifth lens L5, a third mirror M3, and a fourth mirror M4 but is not limited thereto.

In some embodiments, the second relay optical system 500 may be configured to allow the optical signal generated by the second light source 400 to be incident to the back surface of the measurement target MT. The third detector 600 may be configured to measure the measurement target MT based on an optical signal reflected in the vicinity of the back surface of the measurement target MT. For example, the third detector 600 may be configured to measure the measurement target MT by using interference measurement. The second shape profile measurement device IA2 may measure the measurement target MT based on an optical signal of a wavelength band having a high transmittance with respect to the measurement target MT. However, the second shape profile measurement device IA2 is not limited thereto and may include other devices capable of measuring the measurement target MT.

The shape profile measurement device 1000 of the inventive concept may measure the measurement target MT by allowing an optical signal to be incident to each of the front surface and the back surface of the measurement target MT. Therefore, the measurement target MT may be measured with high reliability. In addition, the shape profile measurement device 1000 of the inventive concept may perform measurement based on different wavelength bands respectively applied to the upper surface and the lower surface of the measurement target MT.

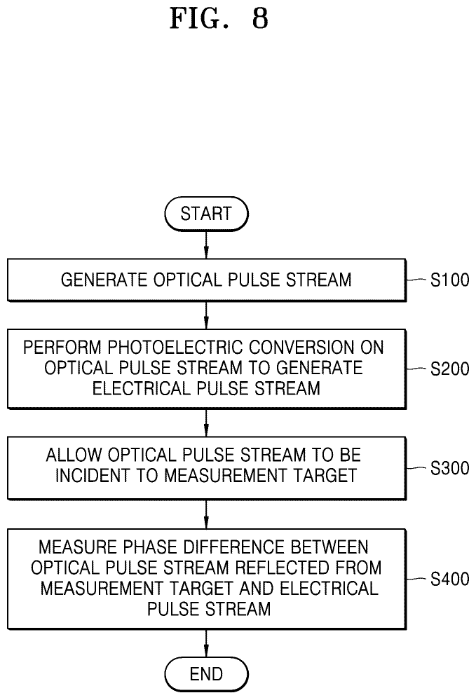

FIG. 8 is a flowchart illustrating a shape profile measurement method according to some embodiments. A description is made with reference to FIGS. 1 to 7 together.

Referring to FIG. 8, first, an optical pulse stream for measuring a shape profile may be generated in operation S100. The optical pulse stream may have a wavelength band having a high reflectivity with respect to the measurement target MT. In some embodiments, the optical pulse stream may have wavelength band having a high reflectivity with respect to silicon. For example, the optical pulse stream may have a wavelength band having a high reflectivity of 90 % or higher with respect to silicon. For example, the optical pulse stream may have a wavelength of 1,000 nm or lower.

Thereafter, photoelectric conversion may be performed on at least a portion of the optical pulse stream to generate an electrical pulse stream in operation S200. The electrical pulse stream may be a reference signal for measuring the measurement target MT later. When the optical pulse stream is input to a photoelectric device, the electrical pulse stream may be generated. The photoelectric device may include a PIN optical diode and/or a UTC optical diode.

For example, photoelectric conversion may be performed on the at least a portion of the optical pulse stream to generate a microwave. For example, when the photoelectric device and a BPF are used, the optical pulse stream may be converted into a microwave.

In another embodiment, an additional RF signal source configured to generate a microwave is included, and then the microwave generated by the RF signal source may be synchronized with the optical pulse stream generated in operation S100. Thereafter, the microwave synchronized with the optical pulse stream may be generated.

Thereafter, at least a portion of the optical pulse stream may be incident to the measurement target MT in operation S300. When operation S300 is performed, the behavior of the optical pulse stream may be controlled. For example, the behavior of the optical pulse stream may be controlled by a galvano scanner and/or a rotating mirror. In addition, when operation S300 is performed, the optical pulse stream may be dispersed according to wavelengths. For example, the optical pulse stream may be dispersed by a prism, a spectrometer, and/or a diffraction grating.

When the behavior of the optical pulse stream is controlled and/or the optical pulse stream is dispersed according to wavelengths, the shape profile of the measurement target MT may be quickly acquired. When the behavior of the optical pulse stream is controlled, movement of the optical pulse stream may be quick, and when the optical pulse stream is dispersed, the measurement target MT may be line-scanned to quickly measure the measurement target MT.

Thereafter, the phase difference between a reflected optical pulse stream and the electrical pulse stream may be measured to measure the shape profile of the measurement target MT in operation S400. Operation S400 may be performed based on TOF. The shape profile of the measurement target MT may be measured based on the phase difference between the electrical pulse stream generated in operation S200 and the optical pulse stream reflected from the measurement target MT. In more detail, an electrical signal may be acquired based on the phase difference between the electrical pulse stream and the optical pulse stream reflected from the measurement target MT, and the depth of a pattern may be measured based on the electrical signal.

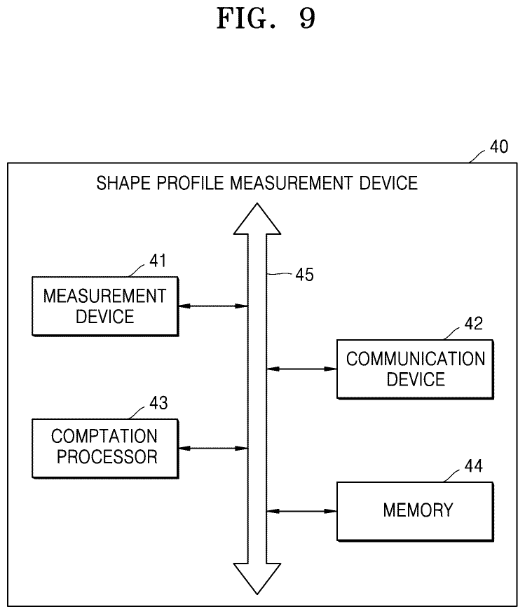

In some embodiments, operation S400 may include acquiring a line scan image of the measurement target MT and then measuring the measurement target MT based on the line scan image. As described above, the line scan image may be acquired based on the electrical pulse stream and the optical pulse stream reflected from the measurement target MT. For example, operation S400 may include measuring the vertical level (i.e., the shape profile) of each area of the measurement target MT (e.g., each pixel of an image of the measurement target MT) based on the intensity of light in each area of the measurement target MT. For example, operation S400 may include measuring the vertical level (i.e., the shape profile) of each area of the measurement target MT based on the wavelength band of an optical pulse stream incident to each area of the measurement target MT and the intensity of light in each area of the measurement target MT. In an embodiment, the detector 300 may include a scan camera 310 generating a scan line image corresponding to the chromatically dispersed light over a plurality of wavelength bands. The scan line image includes a plurality of regions corresponding to the plurality of wavelength bands. The detector 300 is configured to detect a plurality of intensities of the plurality of regions of the scan line image. A computation processor 43 (i.e., a processor), as shown in FIG. 9, is configured further to calculate a vertical level of each region of the plurality of regions based on a corresponding intensity of the plurality of intensities and a corresponding wavelength band of the plurality of wavelength bands.

In addition, an inspection on the measurement target MT may be performed based on the shape profile acquired in operation S400. The acquired shape profile may be compared with a designed shape profile, when the difference between the two profiles is within an allowable error range, it may be determined that the measurement target MT is normal, and when the difference between the two profiles is out of the allowable error range, it may be determined that the measurement target MT is abnormal. The designed shape profile may be a target profile which may be obtained by simulation or obtained from a target device with the target profile.

When it is determined that the measurement target MT is abnormal, a post process on the measurement target MT may be performed. For example, a process of manufacturing the measurement target MT may be corrected. For example, correcting the process of manufacturing the measurement target MT may include correcting a parameter of the process of manufacturing the measurement target MT.

FIG. 9 is a schematic block diagram of a shape profile measurement device 40 according to some embodiments. A description is made with reference to FIGS. 1 to 8 together.

Referring to FIG. 9, the shape profile measurement device 40 may include a measurement device 41, a communication device 42, a computation processor 43, a memory 44, and a bus 45. However, the components included in the shape profile measurement device 40 are not limited to the components listed above, and the shape profile measurement device 40 may include other components configured to measure the measurement target MT including a pattern. The components included in the shape profile measurement device 40 may communicate with each other via the bus 45.

The measurement device 41 may measure the measurement target MT including the pattern. For example, the measurement device 41 may include a device configured to measure the measurement target MT by using a TOF scheme. For example, the measurement device 41 may include a light source configured to generate and emit an optical pulse stream of a wavelength having a high reflectivity with respect to the measurement target MT. For example, the measurement device 41 may include the line scan camera as shown in FIG. 2. For example, the measurement device 41 may acquire a line scan image.

The communication device 42 may provide network communication to the shape profile measurement device 40. A network for the network communication may be a wired network and/or a wireless network, such as a radio network, a cellular network, a satellite network, and/or a broadcast network. In an embodiment, the shape profile measurement device 40 may be an electrical device in which an image processing program is installed, such as a computer, a smartphone, a personal computer, or a server.

The computation processor 43 may perform computation on data acquired by the measurement device 41. The computation processor 43 may perform computation on the phase difference between an electrical pulse stream and an optical pulse stream. The computation processor 43 may perform computation on the shape profile of the measurement target MT based on the phase difference.

In some embodiments, the computation processor 43 may perform computation on the line scan image acquired by the measurement device 41. The computation processor 43 may perform computation on the vertical level of each area of the measurement target MT (e.g., each pixel of an image of the measurement target MT) based on the intensity of light in each area of the measurement target MT. For example, the computation processor 43 may perform computation on the vertical level of each area of the measurement target MT based on the wavelength band of an optical pulse stream incident to each area of the measurement target MT and the intensity of light in each area of the measurement target MT.

For example, the computation processor 43 may include a central processing unit (CPU), a graphics processing unit (GPU), a vector processor, a quantum computation processor, or an embedded computation processor.

The memory 44 may store data computed by the computation processor 43. The memory 44 may store data acquired by the measurement device 41. For example, the memory 44 may include flash memory, a hard disk drive (HDD), a solid state drive (SSD), dynamic random access memory (DRAM), or static random access memory (SRAM).

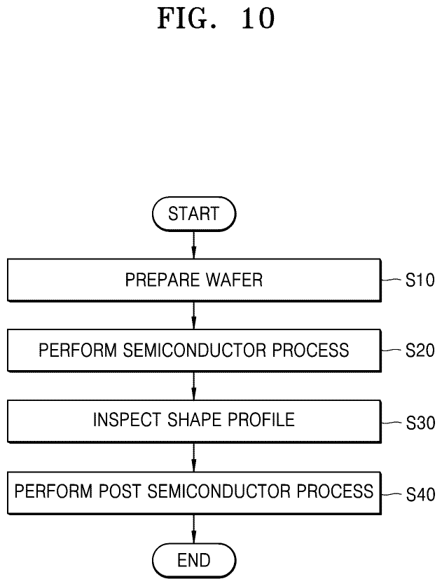

FIG. 10 is a flowchart illustrating a semiconductor device manufacturing method including a shape profile measurement method, according to some embodiments. A description is made with reference to FIGS. 1 to 9 together.

Referring to FIG. 10, first, the wafer W may be prepared in operation S10. For example, one or more semiconductor processes have been performed on the wafer W, or the wafer W may include a bare wafer on which no semiconductor process has been performed.

Thereafter, a semiconductor process may be performed on the wafer W in operation S20. An oxidation process, a photo process, a deposition process, an etching process, an ionization process, and/or a cleaning process may be performed on the wafer W. A pattern may be formed on the wafer W by performing the semiconductor process on the wafer W. In some embodiments, at least a portion of the wafer W may be removed in the vertical direction (the Z direction) to form a pattern extending in the vertical direction (the Z direction). In another embodiment, a plurality of layers may be formed on the wafer W, and then at least some of the plurality of layers may be removed in the vertical direction (the Z direction) to form a pattern extending in the vertical direction (the Z direction).

Thereafter, a shape profile may be inspected in operation S30. Operation S30 of inspecting the shape profile may include operation S100 of generating an optical pulse stream, operation S200 of generating an electrical pulse stream by photoelectric-converting at least a portion of the optical pulse stream, operation S300 of allowing the optical pulse stream to be incident to the measurement target MT, and operation S400 of measuring the shape profile by measuring the phase difference between a reflected optical pulse stream and the electrical pulse stream in FIG. 8.

Thereafter, a post semiconductor process may be performed on the wafer W in operation S40. The post semiconductor process on the wafer W may include various processes. For example, the post semiconductor process may include an oxidation process, a photo process, a deposition process, an etching process, an ionization process, or a cleaning process. In addition, the post semiconductor process may include a singulation process of individualizing the wafer W into individual semiconductor chips, a test process of testing the semiconductor chips, and a packaging process of packaging the semiconductor chips. A semiconductor device may be completed through the post semiconductor process on the wafer W.

While the inventive concept has been particularly shown and described with reference to embodiments thereof, it will be understood that various changes in form and details may be made therein without departing from the spirit and scope of the following claims.

What is claimed is:

1. A shape profile measurement device comprising:
a light source configured to emit an optical pulse stream;
a relay optical system configured to:
receive the optical pulse stream which is deflected into a first portion of the optical pulse stream and a second portion of the optical pulse stream,
generate an electrical pulse stream from the first portion of the optical pulse stream,
generate a chromatically dispersed light over a plurality of wavelengths from the second portion of the optical pulse stream,
provide the chromatically dispersed light to a measurement target, and
output a reflected optical pulse stream reflected from the measurement target;
a detector configured to receive the electrical pulse stream and the reflected optical pulse stream from the relay optical system and detect a phase difference between the electrical pulse stream and the reflected optical pulse stream; and
a processor configured to generate a shape profile of the measurement target using the phase difference.

2. The shape profile measurement device of claim 1,
wherein the relay optical system comprises an electrical pulse stream generator configured to convert the first portion of the optical pulse stream into the electrical pulse stream.

3. The shape profile measurement device of claim 1, wherein the relay optical system comprises a chromatic aberration generator including at least one of a prism, a diffraction grating, and a spectrometer and configured to disperse the second portion of the optical pulse stream according to the plurality of wavelengths to generate the chromatically dispersed light over the plurality of wavelengths.

4. The shape profile measurement device of claim 1,
wherein the relay optical system comprises a scanning system configured to change a traveling direction of the second portion of the optical pulse stream.

5. The shape profile measurement device of claim 4,
wherein the scanning system comprises at least one of a galvano scanner and a rotating mirror.

6. The shape profile measurement device of claim 1,
wherein the optical pulse stream has a wavelength band having a reflectivity of 90 % or higher with respect to the measurement target.

7. The shape profile measurement device of claim 1,
wherein the light source comprises a femtosecond laser configured to generate a femtosecond-scale optical pulse stream.

8. A shape profile measurement device comprising:
a light source configured to emit an optical pulse stream;
a relay optical system comprising:
a deflector configured to receive the optical pulse stream and deflect the optical pulse stream into a first portion of the optical pulse stream and a second portion of the optical pulse stream,
an electrical pulse stream generator configured to convert the first portion of the optical pulse stream into an electrical pulse stream,
a scanning system configured to change a traveling direction of the second portion of the optical pulse stream, and
a chromatic aberration generator configured to:
receive the second portion of the optical pulse stream from the scanning system,
disperse the second portion of the optical pulse stream over a plurality of wavelengths to generate a chromatically dispersed light, and
output the chromatically dispersed light to a measurement target;
a detector configured to receive a reflected optical pulse stream reflected from the measurement target as a line scan image and the electrical pulse stream; and
a processor configured to generate a shape profile of the measurement target based on the line scan image.

9. The shape profile measurement device of claim 8,
wherein the detector includes a scan camera generating the line scan image corresponding to the reflected optical pulse stream,
wherein the reflected optical pulse stream corresponds to the chromatically dispersed light over the plurality of wavelengths reflected from the measurement target,
wherein the line scan image includes a plurality of regions corresponding to the plurality of wavelengths, respectively,
wherein the detector is configured further to detect a plurality of intensities of the plurality of regions of the line scan image, and
wherein the processor is configured further to calculate a vertical level of each region of the plurality of regions based on a corresponding intensity of the plurality of intensities and a corresponding wavelength of the plurality of wavelengths.

10. The shape profile measurement device of claim 8,
wherein the electrical pulse stream generator comprises a photoelectric device configured to convert the optical pulse stream into the electrical pulse stream.

11. The shape profile measurement device of claim 8,
wherein the relay optical system further comprises a radio frequency (RF) signal source configured to generate a microwave,
wherein the microwave is synchronized with the optical pulse stream generated by the light source, and
wherein the detector is configured further to detect a phase difference between the microwave and the reflected optical pulse stream reflected from the measurement target.

12. The shape profile measurement device of claim 8,
wherein the optical pulse stream has a wavelength band having a reflectivity of 90 % or higher with respect to silicon.

13. The shape profile measurement device of claim 8,
wherein the optical pulse stream has a wavelength band of 1,000 nm or lower.

14. The shape profile measurement device of claim 8,
wherein the scanning system comprises at least one of a galvano scanner and a rotating mirror, and
wherein the chromatic aberration generator comprises at least one of a prism, a diffraction grating, and a spectrometer.

15. The shape profile measurement device of claim 8,
wherein the light source comprises at least one of a mode-locked laser, an optical frequency comb, a titanium (Ti)-sapphire laser, and a second harmonic generation (SHG) laser.

16. A shape profile measurement method comprising:
generating and emitting an optical pulse stream;
deflecting the optical pulse stream into a first portion of the optical pulse stream and a second portion of the optical pulse stream;
generating an electrical pulse stream by converting the first portion of the optical pulse stream to the electrical pulse stream;
probing a measurement target with the second portion of the optical pulse stream; and
measuring a surface profile of the measurement target based on a reflected optical pulse stream reflected from the measurement target and the electrical pulse stream,
wherein the probing of the measurement target comprises:
changing a traveling direction of the optical pulse stream to scan the measurement target; and
dispersing the optical pulse stream over a plurality of wavelengths to generate a chromatically dispersed light.

17. The shape profile measurement method of claim 16,
wherein the measuring of the surface profile of the measurement target comprises:
calculating a vertical level of an area of the measurement target based on a phase difference between the electrical pulse stream and a reflected optical pulse stream reflected from the area of the measurement target.

18. The shape profile measurement method of claim 16,
wherein the measuring of the measurement target comprises:
acquiring a line scan image of the measurement target based on the reflected optical pulse stream reflected from the measurement target.

19. The shape profile measurement method of claim 18,
wherein the measuring of the measurement target comprises:
calculating a vertical level of each region of a plurality of regions of the line scan image based on a corresponding intensity of a plurality of intensities and a corresponding wavelength of the plurality of wavelengths, wherein the plurality of regions correspond to the plurality of wavelengths, respectively, and
wherein the plurality of regions have the plurality of intensities.

20. The shape profile measurement method of claim 16,
wherein the measuring of the measurement target is performed in a time of flight (TOF) scheme.
